(19) United States
(12) Patent Application Publication
(10) Pub. No.: US 2016/0369111 A1
(43) Pub. Date: Dec. 22, 2016

(54) SILVER PASTE AND ITS USE IN SEMICONDUCTOR DEVICES

(71) Applicant: Sun Chemical Corporation, Parsippany, NJ (US)

(72) Inventors: Jerome G. MOYER, West New York, NJ (US); Jin-An HE, Mountain Lakes, NJ (US); Bo SUN, Bardonia, NY (US); Maura MOSTOWY-GALLAGHER, Succasunna, NJ (US); Michael J. Jurek, Oak Ridge, NJ (US)

(73) Assignee: Sun Chemical Corporation, Parsippany, NJ (US)

(21) Appl. No.: 15/185,287

(22) Filed: Jun. 17, 2016

Related U.S. Application Data
(60) Provisional application No. 62/182,058, filed on Jun. 19, 2015.

(51) Int. Cl. C09D 5/24; H01L 31/0224

(52) U.S. Cl. CPC C09D 5/24; H01L 31/022425

(57) ABSTRACT

The composition of an electrode thick film paste used in forming electrical contacts with silicon solar cells is disclosed. The thick film paste is comprised of an electrically conductive metal, an organic vehicle system and a system of inorganic additives. The conductive metal is silver and employs a high surface area material in order to improve fine line printing. The organic system makes use of highly soluble binder materials to enable higher loading of the total resin in the paste that improves the printability and print qualities of fine lines. The improved solubility also broadens the range of thixotropes that can be used to further improve printed line properties. In the organic system, a high surface tension solvent is used to improve line quality metrics such as ‘aspect ratio’. The inorganic glass and additives include compounds of lead, tellurium and thallium that improve the electrode contact to, and light conversion efficiency of, the silicon solar cell.

### CROSS REFERENCE TO RELATED APPLICATIONS

This application claims priority to U.S. Provisional Patent Application Ser. No. 62/182,058 filed Jun. 19, 2015, which is incorporated herein by reference in its entirety and for all purposes.

### FIELD OF THE INVENTION

The present invention is directed to a thick film silver paste and its use in the manufacture of semiconductor devices such as photovoltaic cells, and in particular solar cells. The thick film silver paste exhibits an improvement in fine line printing and improves the electrode contact in the devices which consequently exhibit improved efficiency.

### BACKGROUND TO THE INVENTION

The present invention is directed to a thick film silver paste. The silver pastes can include elemental thallium or thallium containing compounds, can be formulated with silver powder having a high specific surface area and/or formulated with solvents that have a high surface tension. These formulations enable the incorporation of higher amounts of resin into the silver paste.

The photovoltaic (PV) industry is rapidly growing and silicon solar cells comprise about 80% of the PV market. A silver (Ag) paste is typically screen-printed with a grid pattern on the front-side (facing the sunlight) of a silicon wafer, and co-fired with the printed back-side aluminum (Al) and back-contact Ag pastes in order to form a circuit. The front silver paste that forms the electrode has a major impact on the silicon solar cell's light conversion efficiency through three mechanisms, namely 1) it defines the contact resistance between the Ag grid and silicon wafer through its constituent glass system, which enables the etching or penetration of the Anti-Reflective Coating (ARC) layer that coats the silicon's surface; 2) the compositional design of the paste impacts the ability to print narrow grid lines with a high aspect ratio, thus increasing the electrical current of the solar cell and 3) functional additives, such as metal oxides and glass modifying compounds facilitate the formation of a low-resistance, ohmic contact with the lightly doped silicon emitter. The lightly doped emitter provides less recombination, thus improving the cell's voltage and current outputs and therefore its efficiency.

U.S. Pat. No. 8,969,709 B2, U.S. Pat. No. 8,497,420 B2 and EP 2 617 689 all disclose the use of lead and tellurium oxides in conductive compositions and pastes.

US 2014/0042375 A1 discloses a paste composition for solar cell electrodes which has a conductive powder and an organic vehicle and glass frits wherein the glass frits contain lead, tellurium and bismuth oxide. The organic vehicle may include hydroxypropylcellulose (HPC) and/or hydroxyethylcellulose (HEC).

EP 2 294 584 A1 discloses a conductive thin film composition containing metal and metal oxide additives, whilst EP 2 566 826 A1 discloses thick film pastes with a lead-tellurium-lithium oxide dispersed in an organic medium and EP 2 566 823 discloses thick film pastes with a lead-tellurium-boron oxides dispersed in an organic vehicle.

Finally U.S. Pat. No. 7,767,254 B2 and US 2013/0180583 A1 are directed to the use of silver particles with a low surface area in a paste for solar cells, whilst US 2013/0340821 A1 uses a specific organic medium in a thick film pastes.

### SUMMARY OF THE INVENTION

The present invention provides a composition for semiconductor devices comprising:
a) a silver powder,
b) glass frits,
c) a resin or rosin,
d) a solvent and
e) elemental thallium or a thallium containing compound.

The present invention also provides a composition for photovoltaic devices comprising:
a) a silver powder having an average specific surface area (SSA) of between 0.7 and 1.2 m²/g,
b) glass frits,
c) a resin or rosin and
d) a solvent.

Furthermore the present invention provides a composition for photovoltaic devices comprising:
a) a silver powder,
b) glass frits,
c) a resin or rosin and
d) a solvent having a surface tension greater than 35 dyne/cm.

The present invention also provides a coated substrate comprising a composition according to the present invention.

Additionally the present invention also provides a process for preparing a coated substrate comprising
a) applying a composition according to the present invention to a surface of the substrate and
b) drying the composition.

Finally the present invention provides a semiconductor device comprising the coated substrate.

These and other objects, advantages, and features of the invention will become apparent to those persons skilled in the art upon reading the details of the methods and formulations as more fully described below.

### BRIEF DESCRIPTION OF THE DRAWINGS

FIG. 1 is a graph of the amount of wet paste transferred to the wafer immediately after printing.

FIG. 2 shows widths of finger lines compared to the average SSA of multiple pastes.

FIG. 3 shows fine line aspect ratios compared to the average silver powder SSA used in the paste.

FIG. 4 shows line widths compared between a control paste and pastes made with High Surface Tensions, HST, solvent systems.

FIG. 5 shows fine lines made from pastes with different loading levels of rosins and resins.

FIG. 6 shows variations on a cellulose structure.

### DETAILED DESCRIPTION

The present invention provides a thick film silver (Ag) paste and its use in the manufacture of semiconductor devices such as photovoltaic devices, particularly solar cells and especially silicon solar cells.

Typically the thick film silver paste includes elemental thallium or thallium containing compounds, a silver powder having a high specific surface area and/or solvents that have a high surface tension.

It has been found that incorporating elemental thallium (Tl) or a thallium containing compound into the composition when the composition is used in the production of a solar cell the solar cell's light conversion efficiency improves due to lower contact resistance between the silver fine lines and the silicon.

In one embodiment of the invention the elemental thallium or thallium containing compounds may be incorporated into the composition as a discrete additive.

In another embodiment of the invention elemental thallium or thallium containing compounds can be incorporated into the glass frits.

Combinations of lead (Pb) and tellurium (Te) have been previously used in glass frits to have been added to improve performance and more recently elements of bismuth (Bi), boron (B) and lithium (Li) to the Pb—Te system.

In a particularly preferred embodiment the present invention provides a glass frit containing Pb and Te wherein elemental thallium or a thallium containing compound has been incorporated therein and it has been found that pastes containing these Pb—Te—Tl glass frits exhibit lower series resistance.

Advantageously the Pb—Te—Tl glass frits may also contain bismuth.

This reduction in series resistance derives from a drop in contact resistance, which raises the ‘fill factor’ and therefore increases the efficiency.

The performance improvement relates to Tl's impact on glass flow properties, in that it enables flow and function at even lower temperatures than the Pb—Te containing glass frits.

Silver powders have been previously used in conductive compositions and the focus has been reducing particle diameters and reducing the surface areas of these powders.

However, it has now been found that using a high average specific surface area (SSA) silver powder delivers a pathway to improve the print quality of the electrode paste. In particular, the high surface area powder reduces the spreading of fine lines as they are being screen printed onto the solar cells and thus the area of the solar cell exposed to light increases.

Furthermore it has been found that the use of high surface tension solvents in the organic vehicle of the paste provides a parallel pathway to improve the print quality of the electrode paste. Employing these solvents also reduces the spreading of fine lines by raising the surface energy of the paste at the interface with the silicon.

The thallium containing compound may be a thallium oxide or thallium salt or an organothallium compound.

Typically the thallium containing compound is a selected from thallium (I) oxide, thallium (III) oxide, thallium(I) bromide, thallium(I) carbonate, thallium(I) oxalate, thallium(I) iodide, thallium(I) fluoride, thallium(I) nitrate, thallium(I) sulfate, thallium(I) ethoxide, thallium(III) acetate, thallium(III) trifluoroacetate, thallium(I) hexafluorophosphate, thallium(I) 2-ethylhexanoate, and/or thallium(I) hexafluoro-2,4-pentanedionate.

Usually the composition according to present invention contains between 0.05 to 5 wt % of elemental thallium or the thallium containing compound, preferably between 0.1 to 3 wt %.

The silver powder has a specific surface area (SSA) of between 0.7 and 1.2 m² and usually a particle size D50 of between 0.1 to 5 μm, advantageously a particle size D50 of between 0.5 to 2 μm where D50 refers the mass-median-diameter, considered to be the average particle size by mass.

Furthermore the Ag powder(s) may be pre-coated with different surfactants to avoid particle agglomeration and aggregation. The surfactant is advantageously a straight-chain, or branched-chain fatty acid, a fatty acid ester, fatty amide or a mixture thereof.

Usually when two or more Ag powders are used a higher Ag particle packing density is achieved and the proximity of the Ag particles facilitates Ag densification during the firing process. This results in a more connected conduction path which generally improves the solar cell efficiency.

The Ag powder(s) are not limited in morphology and may be spherical, elliptical, etc. and typically could be thermally sintered to form a conductive network during the solar cell metallization firing step.

The compositions may contain between 1 to 99 wt % silver powder, typically contain between 5 to 95 wt % silver powder, preferably between 75 to 95 wt % silver powder and advantageously contains between 85 to 95 wt % silver powder, such as between 85 to 90 wt % silver powder.

Typically the silver powder has a purity of greater than 99.5% and usually contains impurities such as Zr, Al, Fe, Na, Cl, K, Pb preferably at concentrations less than 100 ppm.

Typically glass frits are added to the paste compositions to etch through the oxide, nitride or carbide based anti-reflective coating, ARC, and layer(s) on the surface of the silicon wafer.

The glass frit may contain Tl₂O₃, TeO₂, PbO, Bi₂O₃, PbF₂, Al₂O₃, SiO₂, B₂O₃, Li₂O, Li₃PO₄, TiO₂, ZnO, P₂O₅, V₂O₅, SrO, CaO, Sb₂O₃, SO₂, As₂O₃, Bi₂O₃, Ga₂O₃, MgO, Y₂O₃, ZrO₂, Mn₂O₅, CoO, NiO, CuO, SrF₂, Mo₂O₃, WO₃, RuO₂, CdO, In₂O₃, SnO₂, La₂O₃, BaO, BaF₂, LaF₃, ReO₂, ReO₃, Re₂O₇, Tb₂O₃, Tb₄O₇, and/or OsO₄.

In one embodiment of the invention the glass frits contain Tl₂O₃ and TeO₂ and the compositions and the glass frits are “lead free”.

The composition typically contain between 0.5 to 10 wt % of glass frits and advantageously between 1 to 5 wt % of glass frits.

Usually the glass frit contains between 0.1 to 50.0 wt % of elemental thallium or the thallium containing compound.

Typically the glass frits contains between 25 to 65 wt % of lead and advantageously between 30 to 55 wt % of lead.

Furthermore the glass frits usually contain between 30 to 60 wt % of tellurium and advantageously between 35 to 55 wt % of tellurium.

Typically the resin or rosin is selected from the group consisting of acrylic resin, epoxy resin, phenol resin, alkyd resin, cellulose polymers, polyvinyl alcohol, rosin and mixtures thereof.

Advantageously the resin or rosin should burn off during the firing of the coated silicon wafer such that no residue remains thereon.

Advantageously the resin or rosin contains hydroxypropylcellulose (HPC) and/or hydroxyethylcellulose (HEC).

The compositions typically contain 0.2 to 3.0 wt % resin or rosin and advantageously between 0.5 to 1.5 wt % resin or rosin.

The solvents may be selected from anyone of texanol, propanol, isopropyl alcohol, ethylene glycol and diethylene glycol derivatives, toluene, xylene, dibutyl carbitol, terpineol and mixtures thereof.

Wherein the solvent has a surface tension greater than 35 dyne/cm the solvent is typically selected from ethylene glycol, dimethylethanolamine (2-(dimethylamino) ethanol, 2-aminoethanol (ethanolamine), 1,2-propanediol (propylene glycol), 1,3-butanediol, diethylene glycol, dipropylene glycol, aniline, water, glycerol, 1,5-pentanediol, benzyl alcohol, 3-methylphenol (m-Cresol) and mixtures thereof.

The solvent is preferably effective for dissolving the resins, rosins, and thixotropic agents. It assists to improve paste print quality and thoroughly evaporates during the paste drying step.

It has been found that employing a solvent with high static surface tension (>30 dyne/cm) reduces the spreading of fine line structures, which increases the area available for light collection and increases solar cell efficiency. The high surface tension solvent preferably is a polar solvent. Examples of the solvents include benzylalcohol, triethanolamine, Dowanol PPh, water, ethylene glycol, polyethylene glycol, N-Methyl-2-pyrolidon, N,N-dimethylformamide.

Typically the compositions contain between 2 to 20 wt % of solvent and advantageously between 2 to 8 wt % of solvent.

The organic system in the composition is referred to as the vehicle, and preferably contains a thixotropic agent and/or a cellulosic binder.

In a preferred embodiment of the invention hydroxypropylcellulose and/or hydroxyethylcellulose are used in the vehicle and are extremely soluble in a broad range of solvents including the above mentioned high surface tension solvents such as water.

It has been found that hydroxypropyl and hydroxyethyl substituted cellulose improves the solubility parameters, increases the amount of binder that can be loaded into a paste and expands the range of thixotropes that can be implemented into the vehicle.

These readily soluble celluloses also compensate for viscosity increases resulting from the replacement of low SSA, Ag powders with high SSA Ag powders, thus achieving a more ideal flow behavior from the paste with the presence of HPC and/or HEC in the vehicle system.

Furthermore the unique glass frits used in the compositions improve the contact resistance at the electrical contact formed between the paste and a silicon solar cell. The improved contact resistance translates to higher efficiency solar cells. The glass oxides provide uniform bonding strength and improve the adhesion of Ag electrode on solar cells.

Additionally higher efficiency cells can be produced by customers and solar cell manufacturers to reduce their ‘cost-per-watt’ by using the silver based electrode paste according to the present invention and reducing the cost per watt is the value proposition that sells this type of product.

Increasing the resin and rosin content of the compositions provides a paste that can produce line edges that are straightened and fine lines that are narrowed.

However, with higher resin and rosin content the ‘printability’ of the paste can be compromised by increased tackiness, where ‘printability’ is defined as good paste transfer in continuous and valley-free lines.

It has now been found that the use of HPC and (HEC) enables a higher resin loading based on their substitution on the resins and the solubility parameter changes that this provides.

These particular resins have excellent solubility in the range of solvents pertinent to this class of thick film silver based pastes. HEC is water soluble, which makes it extremely valuable for the introduction of high surface tension solvents such as water. The enhanced solubility in these solvents increases the amount of resin that can be added, which improves line quality features including; straighter edges and reduced line spreading. Moreover, these resins exhibit improved solubility and increases their utility with a wider range of thixotropes, which control the total formulation flow and setup upon printing of the paste.

Additional additives may also be added to the compositions such as organometallic additive or additive selected from other oxides and salts such as PbO, PbF₂, Al₂O₃, SiO₂, B₂O₃, Li₂O, Li₃PO₄, TiO₂, ZnO, P₂O₅, V₂O₅, SrO, CaO, Sb₂O₃, SO₂, As₂O₃, Bi₂O₃, Ga₂O₃, MgO, Y₂O₃, ZrO₂, Mn₂O₅, CoO, NiO, CuO, SrF₂, Mo₂O₃, WO₃, RuO₂, TeO₂, CdO, In₂O₃, SnO₂, La₂O₃, BaO, BaF₂, LaF₃, ReO₂, ReO₃, Re₂O₇, Tb₂O₃, Tb₄O₇, OsO₄.

In a particularly preferred embodiment the present provides a composition for a front contact electrode paste for crystalline silicon solar cells. The paste is comprised of a silver powder where the average value of the powder's SSA is between 0.7 and 1.2 m²/g, at least one organic resin that may include hydroxypropyl cellulose (HPC) or hydroxyethyl cellulose (HEC), at least one solvent that may include a high static surface tension of >30 dyne/cm, and a collection of inorganic compounds that include at least one glass powder, also described as glass frit, comprising between 0 to 65 wt % PbO, 50 to 60 wt % TeO₂, and 0.1 to 50 wt % Tl₂O₃.

In one specific embodiment, the pastes of the present invention could be made as a lead free paste. For this specific case, elemental thallium or Tl compounds in the form of oxides, salts and/or organometallics could be incorporated with some or all of the compounds listed below. Any of these compounds could also accompany Tl to form a “lead free” glass. The non-exclusive list of other materials that could be used in conjunction with Tl, which extends to organometallic forms of their primary elements, includes; Al₂O₃, SiO₂, B₂O₃, Li₂O, Li₃PO₄, TiO₂, ZnO, P₂O₅, V₂O₅, SrO, CaO, Sb₂O₃, SO₂, As₂O₃, Bi₂O₃, Tl₂O₃, Ga₂O₃, MgO, Y₂O₃, ZrO₂, Mn₂O₅, CoO, NiO, CuO, SrF₂, Mo₂O₃, WO₃, RuO₂, TeO₂, CdO, In₂O₃, SnO₂, La₂O₃, BaO, BaF₂, LaF₃, ReO₂, ReO₃, Re₂O₇, Tb₂O₃, Tb₄O₇, OsO₄.

It has been found that the use of silver based paste compositions that contain a silver powder mixture whose average specific surface area falls within a specified range will improve the fine line ‘print quality’. Herein, ‘print quality’ refers to the paste characteristics of; the ability to retain line widths similar to the width of the screen opening it is printed through; minimized bleeding of solvent, silver or glass beyond the printed line edges; retention of straight line edges; and that the aspect ratio or height divided by the width of the fine line approaches or exceeds 0.3.

The composition may also typically contain a thixotropic agent, a dispersant and/or an adhesion promoting agent.

Usually the composition contains between 0.1 to 2.0 wt % and advantageously between 0.5 to 1.5 wt % of a thixotropic agent, between 0.01 to 3.0 wt % of a dispersant and between 0.1 to 0.7 wt % of an adhesion promoting agent.

Typically the thixotropic agent is a cellulosic polymer such as ethyl cellulose, castor oil, hydrogenated castor oil, an amide modified castor oil derivative or a fatty amide. Suitable thixotropic agents can be obtained from Rockwood Additives, Cray Valley or the Troy Corporation. Suitable thixotropic agents include Thixatrol Max, Thixatrol ST and Thixatrol Pro.

The dispersant is typically based on long-chain fatty acids such as stearic acid with a functional amine, acid ester or alcohol groups. Suitable dispersants can be obtained from Akzo Nobel, Byk, Lubrizol or Elementis.

Usually the dispersant is long-chain fatty acid such as stearic acid with functional amine, acid ester or alcohol groups. Suitable dispersants include BYK 108, BYK 111, Solsperse 66000 and Solsperse 27000.

The composition is usually in the form of paste and preferably has a viscosity of between 50 to 250 Pa. S at 10 recipocal second.

The composition is usually in the form of paste that preferably has a viscosity between 50 to 250 Pa*s at 10 reciprocal seconds and 25° C., using a 20 mm diameter, 0 degree cone and plate system. Viscosity tests can be made with an AR-2000 Rheometer, as sold by TA Instruments, or an equivalent piece of equipment.

The present invention also provides a solar cell comprising a silicon wafer and the compositions of the present invention on the front side surface of the silicon wafer.

Finally the present invention provides a process for making a solar cell that entails applying a coating of the composition onto the front side surface of a silicon wafer and then drying the paste.

A particular embodiment of the present invention also provides a process for making a solar cell that involves printing electrodes through applying a coating of the paste onto the front side surface of a silicon wafer as the anode. Furthermore, the printing processes for the back side of the cell usually involve applying two overlapping layers containing silver and aluminum respectively to the back side surface of the silicon wafer as the cathode. The metallized silicon wafer is then fired.

The front contact paste composition is usually deposited on a silicon wafer by screen printing through a stainless steel mesh screen. A squeegee is used to push the paste across the screen. Areas of the screen, where the ink should not be printed onto the cell, are masked with an emulsion. Only screen areas without the emulsion allow the paste to be transferred onto the cell. The stroke movement across the screen provides a high shear rate that thins the viscoelastic paste as it rolls over and passes through micro-channels of mesh pattern. The size of the micro-channels are determined by the mesh type, which ranges from 200 and 400 wires per inch and the diameter of those wires that span from 10-20 μm. The fine grid lines, or “fingers”, are preferably as narrow as possible to leave more open area for sunlight collection, but wide enough to maintain good print quality. The height of the printed fingers after firing is typically between 10 to 40 microns. Tall fingers that are continuous, without roughness or valleys, cause less resistance to electrical current and can improve the solar cell's efficiency. Analogous to this concept is the selection of the correct diameter for a copper wire. The wire needs to carry the specified amount of current without getting too hot from the resistive heating losses. Similarly, the grid lines can undergo resistive heating losses that lower the cell efficiency. Crimps in a copper wire cause that circuit to fail, similar to discontinuities in a grid line.

Since the present invention is used in the manufacture of crystalline silicon solar cells, a typical, non-limiting description of that processing follows. Solar cell manufacturers begin with doped silicon wafers of either p-type or n-type. As the majority of the market uses p-type wafers for the cell's base material, the focus will be on the processing for this type of photovoltaic device.

The wafer is minimally doped with p-type elements such as boron at low concentrations of 1E×10¹⁶ atoms/cm³. The incoming wafer is chemically cleaned to reduce impurities that could impact the silicon's optical or electrical properties. The wafer is then chemically textured to make it less reflective to improve the light capturing capabilities. The wafer is then exposed to an n-type dopant, such as phosphorus, in either a gaseous or liquid state. The n-type dopant is driven into the silicon by diffusing the wafer at temperatures up to 1000° C. Following the diffusion, a phos-glass layer is chemically removed to expose the doped silicon surface. Phosphorus concentrations remaining at the surface of the wafer are on the order of 1 to 10E×10²⁰ atoms/cm³, or about 1 phosphorous atom for every 1,000 to 10,000 silicon atoms.

The phosphorous concentration drops off below the surface, as is common to a diffusion profile in a solid, until it reaches the same concentration as the boron dopant typically at a depth between 100 nm and 300 nm. The depth of this net-zero charge is the location of the diode, whereby electrical charges preferentially flow in one or the other direction based on the sign of the charge. In this way the conduction electrons are captured by the emitter to diffuse to the anode.

An electrical isolation step is preferred since the top, bottom and side edges may have the n-type dopant diffused into them. One common method to isolate the ‘positive’ side from the ‘negative’ sides of the cell is achieved by chemically removing the doped material from the wafer's edges and the back-side of the cell.

To improve the optical and electrical qualities of the wafer, thin dielectric materials like H:SiNₓ and/or SiOₓ are then deposited on the surface at a total thickness between 70 to 120 nanometers to passivate dangling electric bonds at the surface of the silicon and to provide an anti-reflective coating, ARC, to the silicon.

At this point the wafer has nearly become a working solar cell. When light shines on it electrical current will flow and a voltage drop can be measured between the opposing wafer surfaces. To extract the current and voltage (power) from the cell, electrodes are screen printed onto the wafer. A conductive paste used for making solder joints along a back bus bar are printed onto a minor area on the backside of the cell. The paste is then dried by heating the cell to around 250° C., which volatilizes the solvents out of the paste. A less conductive (e.g. aluminum) paste is printed onto the remaining backside area of the wafer and covers the edges of the bus bars so that current can disperse from the full rear face of the cell. The aluminum paste is then dried. A minor area preferably of less than 8% on the front (sunny) side of the cell is printed with a conductive paste, which is the basis of the present invention, in a grid-like shape for current collection. Narrow grid lines on the screen, which are preferably less that 40 μm wide, are spaced at a separation of about 1.4 mm to help to maximize the amount of light incident on the silicon while reducing the in plane resistance of electrons flowing toward the anode.

A screen-printing process is used to transfer, or print, the metallization pastes onto solar cells. The screen's mesh is made from thin stainless steel wires. The screens used to process the front contact metallization paste have a maximum gap width of 55 μm between the wires. Yet, the paste needs to pass through much narrower gaps of the screen in order to deliver a continuous line. If the paste does not transfer well thru those narrower regions, the tops of the printed grid lines will display a mirror image to the texture of the mesh in the form of hills and valleys.

A careful selection of silver powders and organic ingredients are required to print through such narrow passages and provide adequate leveling to minimize roughness along the line peaks and interruptions of the fine lines. The specific surface area of the silver powder determines its degree of interaction and cohesion with the organic system. This inter-particle interaction is critical to maintaining cohesion in the paste that prevents line spreading. However, excessive cohesion results in a tacky paste that cannot break apart in the printing process causing line breaks or discontinuities.

Other print qualities that impact solar cell efficiency include the paste transfer and aspect ratio (AR) of the printed lines. It is necessary to have adequate silver transferred in continuous lines so that the grid lines, acting as unbroken wires, give minimal resistance to the current flow. In order to achieve adequate transfer, minimize resistance and line spreading and to maximize current, a high aspect ratio of the fine lines needs to be achieved. With line widths of 40 μm, these heights should preferably exceed 12 μm to deliver an aspect ratio (or the line height divided by its base width) of ≧0.3. The use of higher SSA silver powders, those with average values >0.7 m²/g provide one path to obtaining the continuity and other structural requirements for these desired printed line characteristics.

The organic vehicle must deliver the rheology that delivers excellent shear thinning and settling properties without excessive spreading after it is transferred to the wafer. Use of high surface tension solvent can reduce the spreading of these narrow lines during the printing process. This is desirable since narrower lines allow more light to enter the cell, which increases the current and therefore the cell's power output. Binder materials are used to provide particle to particle cohesion so that the paste does not break apart, where the term binder applies to the organic components of the vehicle system that result in particle to particle interaction and may include resins, rosins and thixotropes. This cohesive action reduces the shading of the cell by limiting spreading and retaining straight line edges. The selection of binder material's chain length, its degree of substitution of the hydroxyl groups and the percent loading of these binders will impact the line spreading and influence how clean the line edges are. Identifying a binder that has compatible solubility to a thixotrope is needed to have a homogenous organic vehicle. The degree and type of substitution on the cellulosic chain significantly impact the solubility of the binder material into the solvent.

Following a drying step for the front side paste, the wafer is then “fast fired”, reaching a peak temperature near 800° C., and is then cooled down to room temperature in less than one minute's time. During this firing step the amorphous dielectric anti-reflection coating bonds to the silicon. The aluminum paste reaches a eutectic point with the silicon and functions as a dopant to form a p+ back surface electric field on the cell to force current in the preferred direction.

During the firing step, electrodes are formed between the wafer and the pastes. The paste's binder volatilizes and excess carbon is taken away by the abundant oxygen provided by the glass and other materials in the paste. Glass that flows to the interface with the silicon etches through the oxide and/or nitride insulating layers. The glass remaining amongst the metal increases the cohesive network strength that aids in the adhesion properties to the interconnect wires that will be soldered to the bus bar sections of the finished cell. The conductive powders either sinter into bulk metals, form colloids suspended in the glass matrix at the interface with the silicon, or recrystallize onto the surface of the silicon. The metal and glass form chemical bonds with the silicon.

Conduction across the silicon/metal/glass/metal portion of the electrode is paramount to the finished solar cell's efficiency at converting light into power. The thinner the glass layer is, the better the conduction is and therefore the efficiency. Secondly, the glass composition impacts the magnitude of colloidal loading, solubility of the metal in the glass and the segregation factors of the metal to crystallize onto the silicon surface. The conductivity across this region is measured as “Contact Resistance” (R_{C}) that is inversely proportional to the Fill Factor (FF). Power is calculated by multiplying the short circuit current (Isc) times the open circuit voltage (Voc) times the FF. Cell efficiency is determined by normalizing the power to the cell area.

The printed front grid with high aspect ratio is needed to carry the current with minimal resistance. The cross sectional profile of the grid line may appear triangular, semicircular, (non-)symmetrical bell shape, or a rectangular shape depending on the paste rheology and print processing conditions. The ideal cross-sectional profile is a rectangular shape with an aspect ratio approaching 1.0 or higher.

The present invention has been described in detail, including the preferred embodiments thereof. However, it will be appreciated that those skilled in the art, upon consideration of the present disclosure, may make modifications and/or improvements on this invention that fall within the scope and spirit of the invention.

The invention is further described by the examples given below.

### EXAMPLES

The following examples illustrate specific aspects of the present invention and are not intended to limit the scope thereof in any respect and should not be so construed.

### Example 1

### Procedure for Making Front Side Ag Paste

Step 1—The vehicle in Table 1 was made by dissolving the rosins and cellulose resins (ingredients 4, 5, 7, 8) in a solvent mixture (ingredients 1-3). High viscosity cellulose materials were used for ingredients 7, 8 and 9. After combining the solvents, rosins and cellulose resins, this solution was mixed using a dispersion blade mounted on an air mixer. The mixture was brought up to 60° C. on a hot plate with a ramp rate of roughly 4° C./minute. After complete dissolution of the binder materials, the solution was cooled to room temperature.

Step 2—The thixotrope, ingredient 6, was then mixed with the dispersion blade and air mixer into this solution for 30 minutes. This mixture was slowly brought up to 60° C. at a rate of −2° C./minute while continuously stirring. After spending 60 minutes at temperature, the blend was removed from heat and agitation.

The mixture above comprises the organic vehicle that coats the glass frit, Ag powders and additives. It enables the paste to become more fluid when subjected to a shear force. This shear thinning behavior gives the paste adequate fluidity to pass through the micron scale stainless-steel mesh channels and the underlying emulsion to be deposited as fine grid lines on the silicon wafer. Additionally, the vehicle provides the paste with a viscoelastic nature, which rapidly diminishes the flow of the paste when it is deposited onto the wafer and the shear force is removed. This elasticity keeps the paste from spreading. The resulting narrow lines provide more area for capturing sunlight to convert to electricity.

TABLE 1
The general formulation for the organic vehicle used to make the
front side Ag paste is provided below. The findings disclosed in
Examples 4 & 5 require modifications to this formulation. Details
are provided in Example 4 as to how the Solvents (Ingredients 1
& 3) are modified with variable X and how, in Example 5, the Cellulosic
binders (Ingredients 7, 8 & 9) are modified thru variable Y. Other
than those exceptions, all other results are based on the general
formulation below with X and Y held at 0.0%.

| Ingre- | Material | | |
|---|---|---|---|
| dient | Type | Material | wt. % |
| 1 | Low surface | 2,2,4- | 41 − X |
| | tension | Trimethylpentanediol | |
| | Solvent | diisobutyrate | |
| 2 | Low surface | 2-(2-Butoxyethoxy)ethyl | 34 |
| | tension | acetate | |
| | Solvent | | |
| 3 | High surface | High surface tension | X |
| | tension | solvent | |
| | Solvent | | |
| 4 | Rosin | Ester of Hydrogenated | 8.0 |
| | | rosin | |
| 5 | Rosin | Pentaerythritol esters | 6.0 |
| | | of hydrogenated rosin | |
| 6 | Thixotrope | Micronized amide | 7.5 |
| | | wax rheology modifier | |
| 7 | Cellulose | Ethyl cellulose | 1.5 |
| | | 48.0-49.5 Ethoxyl % | |
| 8 | Cellulose | Ethyl cellulose | 2.0 − Y |
| | | 50.5-53.8 Ethoxyl % | |
| 9 | Cellulose | hydroxypropylcellulose or | Y (Ex. 5; |
| | alternates | hydroxyethylcellulose | Y = 2.5) |
| | | Total | 100.0 |

Step 3—The dispersant was added to the vehicle along with the glass frit and the additive. These Ingredients 10-13 were mixed on a DAC speed mixer, with model number 400 FVZ, at 2000 rpm for 2 minutes. The container walls were scraped back into the mixture and mixed again at the same settings to obtain a homogenous dispersion.

Step 4—The High SSA silver powder, ingredient 14, was then added to the mixture at 62.02% for all experiments except for those described in Example 3. This was DAC mixed at 1500 rpm for 1 minute. Example 3 provides details on how the value of A is modified particular to that example.

Step 5—The Low SSA silver powder, ingredient 15, was then added to the mixture at (A=) 26.58% for all experiments except for those described in Example 3. This was then DAC mixed at 1500 rpm for 1 minute. The container walls were scraped back into the mixture and mixed again at the same settings, which delivered a homogenous dispersion.

TABLE 2
The general formulation for the front-side silver paste is provided
below. The general paste was based on a mix of the organic vehicle
with a dispersant, glass, additive and silver powders. As Example
3 requires modifications to this formulation, those changes are
reflected by the variables A and B for Ingredients 15 and 16. Other
than the exceptions in Example 3 all other experimental results
are based on the formulation below with Ingredient 14 held at 62.02%,
Ingredient 15 at 26.58% and Ingredient 16 at 0.0%.

| Ingre- | Material | | |
|---|---|---|---|
| dient | Type | Material | wt. % |
| 10 | Vehicle | Vehicle from Table 1 | 7.9 |
| 11 | Dispersant | Dispersant | 1 |
| 12 | Glass | PbO = 45.09, | 2.1 |
| | | Te₂O₃ = 49.21, | |
| | | Tl₂O₃ = 5.70- glass frit | |
| | | (C-1 in Table 6) | |
| 13 | Additives | Bismuth Oxide or other | 0.4 |
| | | cited additives | |
| 14 | Silver - | Ag powder with SSA | 62.02% (Ex. 3; |
| | High | of ~1.05 m²/g | 88.6 − A − B) |
| | SSA | | |
| 15 | Silver - | Ag powder with SSA | A = 26.58 (Ex. 3 → |
| | Low | of ~0.38 m²/g | A = 26.58, 13.29, |
| | SSA | | 4.43 or 0.0) |
| 16 | Silver - | Ag powder with SSA | B = 0.0 (Ex. 3 → |
| | Low | of ~0.56 m²/g | B = 26.58, 13.29, |
| | SSA | | 4.43 or 0.0) |
| | | Total | 100.0 |

Step 6—The paste mixture from Step 5 was then processed on a three-roll mill where it was further de-agglomerated and dispersed. The paste was passed thru an Exakt 80E mill in ‘Gap’ mode. The first, loose, pass was run at 100 rpm with a nip gap of 30 μm and apron gap of 15 μm. The second, medium, pass was run at 100 rpm with a nip gap of 15 μm and apron gap of 10 μm. The final, tight, pass was run at 100 rpm with a nip gap of 10 μm and apron gap of 5 μm.

The 4^{th} scratch method for measuring the Fineness of Grind, FoG, was used. The pastes all were below a grind of 10 μm. The viscosities were measured at 10 reciprocal seconds and 25° C. using a 20 mm diameter, 0 degree cone and plate configuration measured on a TA Instruments AR-2000EX rheometer. The resulting paste viscosities ranged from 60 to 160 Pa*s.

### Example 2

### Solar Cell Fabrication and Test Methods of Pastes

Electrical testing reported in the examples below were measured using 125 mm×125 mm mono-crystalline wafers with an emitter having a sheet resistance of 85+/−10 Ohm/square. Wafer preparation up through the deposition of the anti-reflective coating was conducted by a solar cell manufacturer. The pre-processed wafers were purchased from a cell manufacturer for the development of metallization pastes. The final steps to convert the pre-processed wafers into solar cells included 3 steps:

Step 1—The Al paste was screen-printed on the full back-side of each wafer since performance testing did not require the ‘back contact’/‘tabbing’ Ag paste. The screen used to print the paste had the following parameters; 325 mesh with a 45° bias, 0.9 mil wire diameter, and a 10 μm emulsion over mesh. A squeegee with a shore hardness of 80 was used. The printer settings were; 2.0 mm gap/snap-off, 150 mm/s speed and a force of 8 Kg. These setting deposited 1.0 g+/−0.05 of Al paste onto the wafer. Al printed wafers were then dried in a BTU International D914 dryer with a belt speed of 90 ipm and zone temperatures settings of 310° C., 290° C., and 285° C.

Step 2—The front-side Ag paste was screen-printed on the front surface of the same wafers. The screen used to print the paste had the following parameters; 360 mesh at a 22.5° bias, 0.6 mil wire diameter, and a 15 μm emulsion-over-mesh. A squeegee with a shore hardness of 70 was used. There were 74 finger line openings in the screen, each 45 μm wide. The printer settings were; 2.0 mm gap/snap-off, 150 mm/s speed and a force of 6 Kg. These setting deposited 100 mg+/−30 of Ag paste onto the wafer. The wafers were dried with a belt speed of 165 ipm with zones 1-3 set at the respective temperatures of 340° C., 370° C. and 370° C.

Step 3—The metallized wafers were fired in a BTU International PV309 firing furnace at a belt speed of 220 ipm with zones 1-4 set at 850° C., 790° C., 850° C. and 1000° C.

A Solar Simulator/I-V tester, purchased from PV Measurements Inc., was used to measure the electrical performance metrics of open-circuit voltage (Voc), short-circuit current (Isc), Fill Factor (FF), efficiency (Eff), and series and shunt resistances (Rs, Rsh). The illumination of the lamp was calibrated using a sealed calibration cell, with the measured characteristics adjusted to the standard AM1.5G spectral conditions at 1000 mW/cm². Cells were held by a vacuum on a temperature controlled stage at 25° C. A shutter above the stage opened to shine light from the lamp onto the solar cell. Both dark and light I-V curves were collected by measuring the current output during a voltage sweep between −0.2V up to +1.2V. Data was processed using commercially available computer software.

A Dektak 150 surface profilometer, purchased from Vecco, was used to measure the fine line dimensions at a sub-micron scale resolution. Each cell tested was placed on the vacuum stage of the Dektak, which sat upon an optical table. Lines at the center of the wafer were scanned. The stylus head used was 2.5 μm in diameter. A cross section of each line was measured at 0.083 μm resolution over a 500 μm length. Mapping 100 of these line scans, separated by 10 μm, together gave a topographical map for each line. The resolution parallel to the line direction was 10 μm. The 100 scans across the line delivered statistically relevant data for assessing line widths, heights, cross-sectional areas and aspect ratios. The topographical map shows the print quality and included statistics for surface roughness.

### Example 3

### Impact of Specific Surface Area of Silver Powders on Print Qualities

A particle's surface area can be modified by its texture. This texture will influence how the particle interacts with neighboring particles. Generally speaking, interaction increases with surface area. The specific surface area, SSA, discussed herein is in units of area per unit of mass, m²/g. SSA values provide a value of the average surface area from a group of particles that likely have a range of surface textures and diameters, and therefore a range of individual surface areas. Below we discuss mixing powders with different SSA values. The “average SSA” values described in the data represent the weighted average SSA values from the two constituent powders based on the relative percentage of each powder used.

A series of pastes were made to examine the influence from the specific surface areas (SSA) of the silver powder on the print quality characteristics of the paste. Pastes were made using the general vehicle formulation from Table 1, where X and Y were held at 0, following Steps 1 and 2. The paste was made according to the recipe described by Steps 3-6 and the formulation in Table 2.

To step the values of the Ag powder's average SSA range from 0.86 to 1.05 m²/g in a series of pastes, variable A was adjusted from A=26.58%, 13.29%, 4.43% to 0.0. Data from these pastes are displayed in Graphs 1, 2 and 3.

One of the challenges to screen printing through narrow openings is getting enough material to pass through the screen and deposit itself onto the substrate. Hence a higher transfer amount is desirable since printing parameters such as speed, pressure and snap off may be used to decrease the amount transferred, but the upper transfer amount is limited by the paste rheology. Graph 2 shows how raising the average SSA of the powder mixes increases the amount of paste printed onto the solar cells. This result follows suit to the statement above that higher specific surface area powders deliver more cohesive integrity to the paste.

Taken to the extreme, by using average SSA values exceeding 1.05 m²/g at an 88.6% silver loading level, we observed that pastes become unprintable. When the average SSA is too high, it causes excessive tack in the paste, such that it will not pass through the screen. The tackiness can be addressed by minimally reducing the silver loading down to 88.4%-87.6% in order to obtain a paste with good printability at the higher average SSA of 1.2 m²/g.

Finger lines fired onto solar cells were measured with a surface profilometer to compare line height and width differences between pastes made with the various SSA powder profiles. The desired effect of reducing the line widths, shown in Graph 1, correlates to using higher average SSA mixtures. At the 88.6% silver loading percentage used, good print quality lines were obtained. When average SSA values approached 1.2 m²/g there was deterioration in printability.

To confirm our findings were not specific to a single powder system, an alternate “Low SSA” silver powder was included. The alternate Low SSA paste had an SSA of 0.56 m²/g. While commercially available silver powders have a broad range of surface coatings and morphologies, the alternate powder was selected to mimic the other powder's characteristics in these regards. Thus, maintaining the purpose of the experiment. Similar to the prior pastes, this alternate Ag powder was used to step the values of the average SSA from 0.90 to 1.02 m²/g by adjusting variable B from B=26.58%, 13.29% to 4.43%. Data from these pastes accompany those made by modifying variable A in Graphs 3

Building upon the idea that the cohesive nature of a high SSA powder assists in minimizing line spreading, the idea should translate to raising the fine line's aspect ratio. Graph 3 depicts the AR of pastes using two alternate Low SSA silver powders.

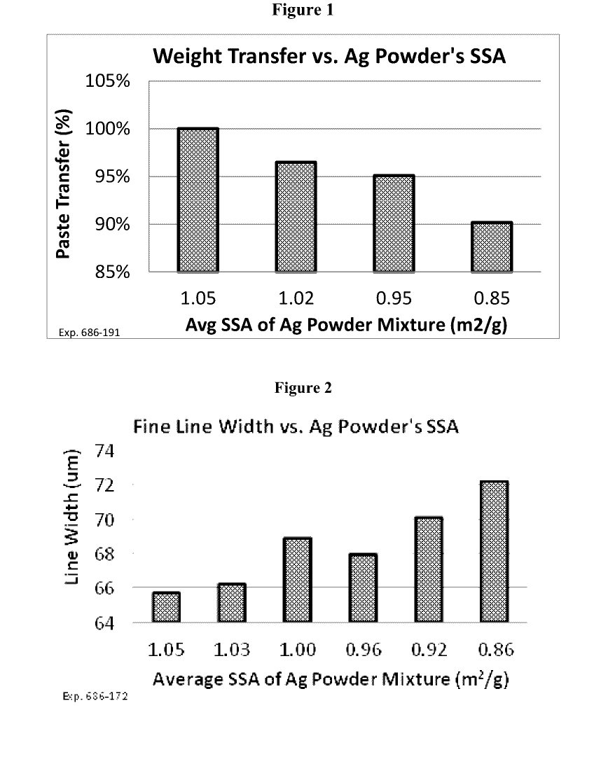

FIG. 1 is a graph of the amount of wet paste transferred to the wafer immediately after printing. The comparison shows that pastes with higher average SSA Ag powder also had greater transfer. The cohesive nature of higher surface area powders raises the amount of paste transferred to the cell.

FIG. 2 shows widths of finger lines compared to the average SSA of multiple pastes. Narrow line widths are desired and are achieved by using powder mixtures with average SSA lower than 0.86 m²/g and above 1.2 m²/g.

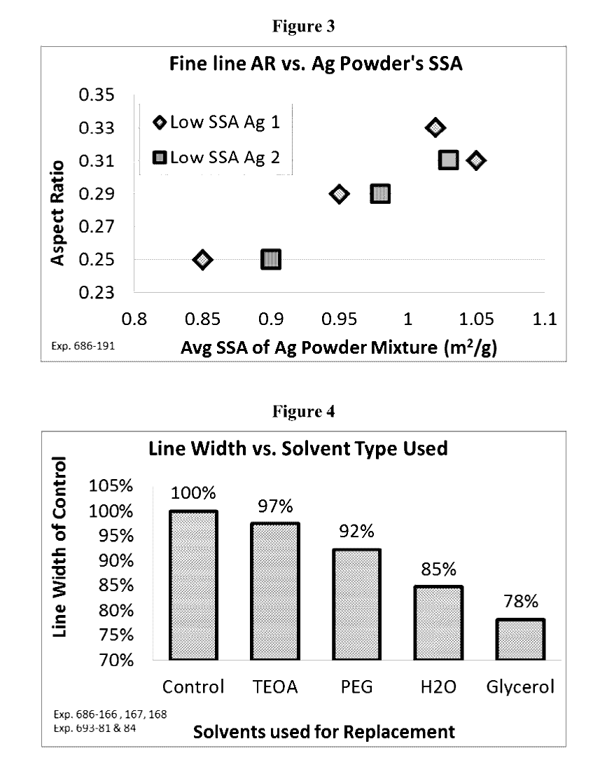

FIG. 3 shows fine line aspect ratios compared to the average silver powder SSA used in the paste. Higher aspect ratios are achieved as the average SSA increases.

In summary, using a silver powder loading level between 87.6% and 88.6% it was found that using average SSA values between 0.7 and 1.2 m²/g provides for excellent paste transfer with narrow lines having high aspect ratios and excellent print quality using narrow, 45 nm, screen openings.

### Example 4

### High Surface Tension Solvents Used in a Paste's Organic Vehicle to Achieve Narrower Line Widths

Solvents with static surface tensions greater than that of the Ingredient 1 solvent 2,2,4-Trimethylpentanediol diisobutyrate, TXIB were tested as partial replacement. We refer to this group of replacement solvents as High Surface Tension, HST, solvents. Table 3 specifies the HST solvents examined and their relative replacement levels of the TXIB. Pastes were made using Steps 1-6 of Example 1 above. However, the solvent addition in Step 1 included a replacement of X % of the 41% TXIB with the Ingredient 3 HST solvents given in Table 3. The final solvent systems, or solvent mixture, used in the pastes tested all included a portion of Ingredient 1, all of Ingredient 2 and a percentage equal to the variable X of the Ingredient 3, provided in Table 3. Cells were processed according to Example 2.

TABLE 3
The control solvent system was modified to increase the overall
surface tension of the solvent package. The surface tensions of
those HST solvents, the % used in the vehicle and the approximated
new surface tensions of the solvent systems are reported.

| | | | Solvent's | | New |
|---|---|---|---|---|---|
| | | | Surface | % Re- | Surface |
| Solvent | | Abbre- | Tension | placed, | Tension |
| System | Solvent name | viation | (dyne/cm) | X = | (dyne/cm) |
| 1 | Table 1 Solvents, | Control | 30 | 0 | 30.0 |
| | Ingredients 1 & 2 | | | | |
| 2 | Triethanolamine | TEOA | 48.4 | 25.3 | 36.2 |
| 3 | Poly ethylene | PEG | 43.5 | 25.3 | 34.6 |
| | glycol 400 | | | | |
| 4 | Deionized water | H2O | 73 | 6.3 | 33.6 |
| 5 | Glycerol | Glycerol | 63.4 | 38 | 46.9 |

The calculated surface tensions, at 25° C., of the modified solvent system are reported in Table 2. The concentrations of the added solvent were minor enough that the overall surface tension of the resultant solvent system remained within 10 to 20 dyne/cm of the control solvent system's surface tension of 30 dyne/cm. Spreading of the fingers, which occurs during the printing and firing procedures, was examined with a surface profilometer on fired solar cells that were made with the series of HST solvent pastes. We observe a reduction of line spreading in conjunction with the solvent system's surface tension is increased from the control solvent systems. The upper range of surface tension came from the addition of glycerol. At that system's surface tension of 46.9 dyne/cm the line quality began to degrade and appeared to appear segmented. Despite the narrow width achieved from the glycerol, the hills and valleys along the line identified an upper limit to the usable surface tension.

FIG. 4 shows line widths compared between a control paste and pastes made with High Surface Tensions, HST, solvent systems. HST systems narrowed fine lines by over 20%.

In summary, all pastes made with HST solvents had narrower fired fine line widths. In addition to the solvents tested, a range of HST solvents suited for this application can be used to assist in the reduction of fine line widths. The appropriate HST solvents need to have low volatility, be environmentally safe and have Hansen solubility parameters that complement the remaining inorganic vehicle ingredients. Additional applicable solvents include, but are not limited to; Ethylene glycol, Dimethylethanolamine (2-(dimethylamino) ethanol, 2-Aminoethanol (ethanolamine), 1,2-Propanediol (propylene glycol), 1,3-Butanediol, Diethylene glycol, Dipropylene glycol, Aniline, water, Glycerol, 1,5-Pentanediol, Benzyl alcohol and 3-Methylphenol (m-Cresol).

### Example 5

### Ethyl Cellulose Alternatives for Improved Solubility, Increased Cohesion and Narrower Fine Lines

The primary goal in developing a vehicle is that it will provide good print quality. Wherein, the attributes of printability encompass: good paste transfer and excellent settling properties to minimized roughness, valleys or line breaks. Once those metrics are passed, the merits of print quality can be considered, specifically; minimal solvent or silver bleeding, minimal line spreading, straight line edges and narrow line widths with high aspect ratios.

One of the difficulties inherent to developing a vehicle system is identifying compatible resin, rosin and thixotrope materials. Ideally the best cellulosic/binder material would deliver high particle interaction, low tack, high solvent retention and excellent solubility in solvents that also solubilize the thixotrope. The thixatrope would provide the shear thinning needed to enable flow at high shear and instantly freeze the flow when the shear is removed, yet enable the leveling agents to smooth paste surfaces not in contact with the silicon. All too often however, solvents that are effective at dissolving cellulosic materials do not dissolve the thixatrope very well and vice versa. In order to obtain compatibility between the resin and thixatrope materials often leads to a compromise in printability and/or print quality.

The loading levels for rosins and resins and thixotropes have a dramatic impact on the printability and print quality. Overall, line qualities of bleed out, narrowness, high aspect ratio and clean line edges are improved by increasing the resin up to the point where the printability suffers. To increase the binder further an alternate resin material must be introduced.

Table 4 illustrates some of the key ideas pertaining to printability and print quality. Paste A did not pass through the screen since there was too much resin causing the paste to be too tacky. The top-down view of Paste B, in Table 4, shows that it did not have adequate binder (resin and rosin) to retain the solvent. The speckled region next to its dried line indicates that silver particles bled out along with the solvent. Despite the high rosin content, paste C did not have adequate resin to retain the solvent resulting in solvent and silver bleed out. While the line from the C paste has more body to it, meaning a larger cross sectional area, the high rosin level resulted in a tacky paste. This is evident by the segmented, centipede-like, structure whose valleys add substantial resistance to the conductive line. Paste D does a better job at retaining the solvent and silver, and it has enough binder to hold a suitable body. The width is much improved over paste A. However, the rough line edges from paste D still create unnecessary shading of the cell. By increasing the Rosin, so as to minimize the additional tack, Paste F presents a picture of a line with fair printability and print quality.

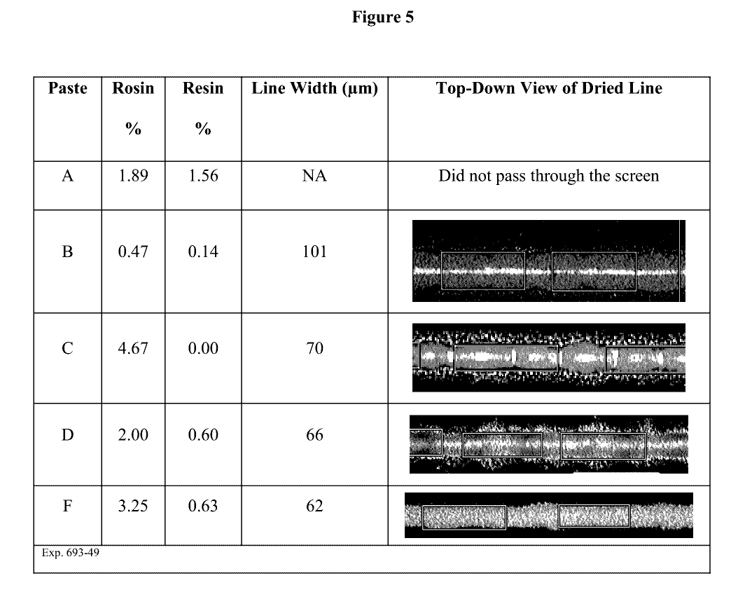

FIG. 5 shows fine lines made from pastes with different loading levels of rosins and resins. The loading levels of the rosins and resins show a strong impact on printability and print quality.

Ethyl cellulose, EC, has been the binder of choice for silver based thick film front contact pastes. However, this resin needs to have its anhydroglucose units substituted with ethoxyl groups to be soluble in the subset of solvents that is suited for solar cell pastes. Commercially available EC resins come in a range of substitution levels from 2.2 to 2.8, with the maximum theoretical degree of substitution being 3. We have found the solubility of lower degree substitution EC to be difficult to dissolve, while higher degree substituted EC readily dissolved. Hence, using the applicable solvents, solubility of the EC increases with the degree of ethoxyl substitution. The cellulose and substituted EC molecules are depicted in FIGS. 1a and 1b.

From that finding, other available binder materials were tested to see if they would be deliver improvements to the binder properties sought. Two materials that stood out were the hydroxypropyl and hydroxyethyl substituted cellulose materials shown in FIGS. 1c and 1d. These materials have the same potential degree of substitution as the EC, but achieving the maximum substitution is far easier due to the simplified manufacturing process. Moreover, HEC and HPC materials have longer side chains than EC, which enable more interaction with surrounding particles.

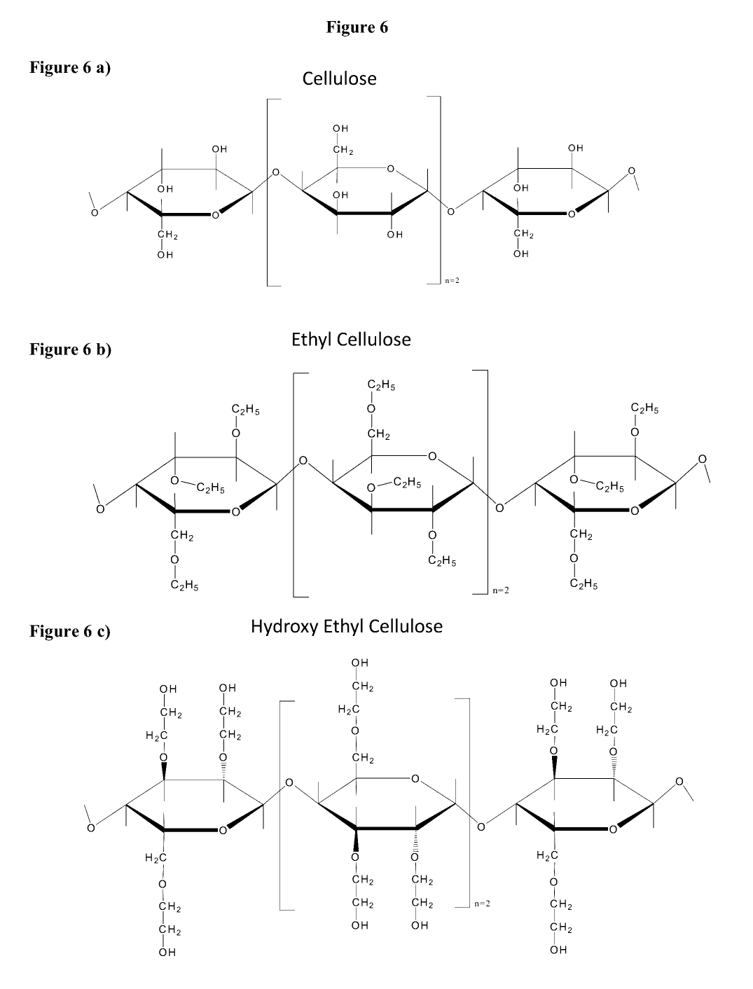

FIG. 6 shows variations on a cellulose structure with; a) the basic structural formula for cellulose, b) the structure after anhydroglucose units is substituted by ethoxyl groups, c) hydroxy ethyl groups and d) hydroxy propyl groups.

Pastes employing these binders were made following the formulation provided in Table 1 and the recipe in Steps 1 thru 6 of Example 1. The variable Y, for Ingredient 9, was held at 2.0 to fully replace Ingredient 8 with the Hydroxypropyl cellulose, HEC, or Hydroxyethyl cellulose, HPC. High viscosity versions of Klucel HPC and Natrosol HEC brand products were used for the two pastes. The HPC and HEC were found to be readily soluble in the paste solvent system of the Table 1 vehicle. Cells were prepared following Example 2.

As previously stated, identifying compatible resin and thixatrope materials is a challenge in the development of vehicle systems that enable fine line printing at high aspect ratios. The potential for compatibility in the HEC and HPC materials is greatly improved over the EC material due to the solubility parameters of these molecules.

Benefiting from the long side chains of the HEC and HPC, an increased particle to particle interaction was observed. This manifested itself by the higher paste cohesion that delivered narrower fine lines. The inclusion of HEC and HPC lowered line widths to 92% and 94% respectively of the control paste line widths. In summary, the findings were that the structure of the hydroxypropyl and hydroxyethyl substitution on the resin, and the solubility parameter changes they bring with them, were beneficial to the vehicle system.

### Example 6

### Pb—Te—Tl Oxide Based Glass

Glass frits were prepared by mixing varied amounts of PbO, TeO₂ and Tl₂O₃ along with other oxides including Al₂O₃, B₂O₃, Bi₂O₃, MoO₃, SiO₂, WO₃ and ZnO. One kilogram of the oxide mixtures were heated in alumina crucibles to 900° C. for one hour and the melt was sparged with oxygen. The melted glass mixture was then poured into deionized water to quench it into a frit. The material was ball milled with an alumina media to lower the particle size distribution to a D50 value below 2.0 μm. The media was then removed and the remaining powder was dried.

Pastes were made with these glass frits using the vehicle and paste formulations in Tables 1 and 2. We followed the recipes provided in Steps 1 thru 6 of Example 1. The compositional variations in the glass frit of Ingredient 12 are reported in Table 5 for each paste in which it was tested. The first column of Table 5 gives a numerical assignment to the experiment in which it was tested and a letter assignment to each paste (i.e., 1=Experiment 1, A=Paste A).

Cells were processed and tested according to Example 2. For each paste in Table 5, 10 or more cells were produced for statistical purposes. The cells from each of the experiments were manufactured at the same time and are known to have nearly identical properties. The reported electrical measurement values, in Table 5, are based on the average of those cells.

The glass composition is known to impact the contact resistance, Rc, between the silicon wafer and the bulk silver of the paste. This impact is apparent in the series resistance, Rs, contribution to the Fill Factor, FF, where Rs is the sum of resistances coming from 1) the bulk silicon; 2) the silicon emitter's sheet resistance; 3) the Rc; and 4) the grid resistance of the fine silver lines and bus bars. Using multiple cells statistically eliminates fluctuations on the Rs due to process, test or material variations. The paste-to-paste variations from grid resistance were minimized by confirming good printability on each cell tested. Therefore, the signal of Rs is dominated by the Rc.

TABLE 5
Multiple experiments were run using various glass systems. The different glass systems
explored how levels of Tl₂O₃ in combination with other materials contained in the
glass affected cell efficiency, FF and Rs. The weight percent of each oxide for the
glass system indicates how the glass composition influences cell performance.

| Experiment - | | | | | | | | | | |
|---|---|---|---|---|---|---|---|---|---|---|
| Paste | Eff | FF | Rs | B2O3 | PbO | SiO2 | TeO2 | Tl2O3 | ZnO | Total |
| 1-A | 18.08 | 77.38 | 1.12 | — | 47.82 | — | 52.18 | — | — | 100.00 |
| 1-C | 18.26 | 77.82 | 1.03 | — | 45.09 | — | 49.21 | 5.70 | — | 100.00 |
| 2-A | 18.08 | 77.02 | 1.15 | — | 47.82 | — | 52.18 | — | — | 100.00 |
| 2-E | 18.19 | 77.37 | 1.10 | — | 45.09 | — | 49.21 | 5.70 | — | 100.00 |
| 2-H | 18.15 | 77.22 | 1.09 | — | 47.71 | — | 52.07 | 0.23 | — | 100.00 |
| 2-L | 18.21 | 77.37 | 1.12 | — | 45.79 | — | 49.97 | 4.24 | — | 100.00 |
| 4-A | 17.90 | 77.48 | 1.07 | — | 47.82 | — | 52.18 | — | — | 100.00 |
| 4-S | 18.00 | 77.71 | 1.05 | — | 45.09 | — | 49.21 | 5.70 | — | 100.00 |
| 4-T | 17.98 | 77.67 | 1.06 | — | 42.42 | — | 49.25 | 8.32 | — | 100.00 |
| 4-U | 17.96 | 77.74 | 1.04 | — | 39.75 | — | 49.30 | 10.94 | — | 100.00 |
| 4-V | 18.03 | 77.91 | 1.00 | — | 37.09 | — | 49.35 | 13.57 | — | 100.00 |
| 4-W | 17.96 | 77.48 | 1.11 | — | 16.18 | — | 49.72 | 34.00 | — | 100.00 |
| 4-X | 18.01 | 77.82 | 1.03 | — | 43.32 | — | 48.68 | 8.00 | — | 100.00 |
| 4-Y | 17.99 | 77.91 | 1.01 | — | 40.17 | — | 47.73 | 12.10 | — | 100.00 |
| 4-Z | 17.99 | 77.88 | 1.01 | — | 43.08 | — | 48.60 | 8.32 | — | 100.00 |
| 4-AB | 18.10 | 78.00 | 0.98 | 1.96 | 36.08 | 2.46 | 39.37 | 18.98 | 1.14 | 100.00 |
| 5-AD | 18.47 | 77.02 | 1.19 | — | 45.09 | — | 49.21 | 5.70 | — | 100.00 |
| 5-AB | 18.44 | 76.81 | 1.21 | 0.63 | 42.21 | 0.79 | 46.06 | 9.95 | 0.36 | 100.00 |
| 5-AE | 18.46 | 77.11 | 1.14 | 1.28 | 39.20 | 1.61 | 42.78 | 14.38 | 0.74 | 100.00 |
| 5-AF | 18.43 | 77.05 | 1.16 | 0.63 | 42.21 | 0.79 | 46.06 | 9.95 | 0.36 | 100.00 |

It was found that including thallium oxide, Tl₂O₃, in a Pb—Te glass system improves solar cell efficiency from the higher Fill Factors that were increased as a result of reduced Rs. The Experiment 1 pastes clearly demonstrate this point as the presence of Tl₂O₃ in 1-C lowers Rs, compared to 1-A, which subsequently raises FF and Eff. Experiment 2 pastes show that levels as low as low as 0.23% (2-H) of the Tl₂O₃ in the glass were effective at improving performance over a paste that did not contain Tl₂O₃ in its glass (2A). This trend continues to remain at a nearly 19% Tl₂O₃ glass in comparing 4-AB to 4-A in Experiment 4. The inclusion of glass components other than Tl₂O₃, extend its functional range to higher concentrations as evidenced by glass compositions from Experiment 4 and 5.

1. A composition for semiconductor devices comprising:
a) a silver powder,
b) glass frits,
c) a resin or rosin,
d) a solvent and
e) elemental thallium or a thallium containing compound.

2. A composition according to claim 1 wherein the thallium containing compound is a thallium oxide or thallium salt.

3. A composition according to claim 1 wherein the thallium containing compound is an organothallium compound.

4. A composition according to claim 1 wherein the thallium containing compound is a selected from thallium (I) oxide, thallium (III) oxide, thallium(I) bromide, thallium(I) carbonate, thallium(I) oxalate, thallium(I) iodide, thallium(I) fluoride, thallium(I) nitrate, thallium(I) sulfate, thallium(I) ethoxide, thallium(III) acetate, thallium(III) trifluoroacetate, thallium(I) hexafluorophosphate, thallium(I) 2-ethylhexanoate, thallium(I) hexafluoro-2,4-pentanedionate.

5. A composition according to claim 1 wherein the elemental thallium or the thallium containing compound is present in the composition as an additive.

6. A composition according to claim 1 wherein the elemental thallium or the thallium containing compound is present in the composition as a component of the glass frit.

7. A composition according to claim 1 wherein the composition contains between 0.05 to 5 wt % of elemental thallium or the thallium containing compound.

8. A composition according to claim 1 wherein the glass frit contains between 0.1 to 50.0 wt % of elemental thallium or the thallium containing compound.

9. A composition according to claim 1 wherein the silver powder has a average specific surface area (SSA) of between 0.7 and 1.5 m²/g.

10. A composition according to claim 1 wherein the resin or rosin is selected from the group consisting of acrylic resin, epoxy resin, phenol resin, alkyd resin, cellulose polymers, polyvinyl alcohol, rosin and mixtures thereof.

11. A composition according to claim 1 wherein the resin or rosin is hydroxypropylcellulose (HPC) and/or hydroxyethylcellulose (HEC).

12. A composition according to claim 1 wherein the solvent is selected from texanol, propanol, isopropyl alcohol, ethylene glycol and diethylene glycol derivatives, toluene, xylene, dibutyl carbitol, terpineol and mixtures thereof.

13. A composition according claim 1 wherein the solvent has a surface tension greater than 35 dyne/cm.

14. A composition according to claim 13 wherein the solvent is selected from ethylene glycol, dimethylethanolamine (2-(dimethylamino) ethanol, 2-aminoethanol (ethanolamine), 1,2-propanediol (propylene glycol), 1,3-butanediol, diethylene glycol, dipropylene glycol, aniline, water, glycerol, 1,5-pentanediol, benzyl alcohol, 3-methylphenol (m-Cresol) and mixtures thereof.
